(19) United States
(12) Patent Application Publication
(10) Pub. No.: US 2018/0294302 A1
(43) Pub. Date: Oct. 11, 2018

(54) IMAGE SENSING CHIP PACKAGING STRUCTURE AND METHOD

(71) Applicant: China Wafer Level CSP Co., Ltd., Suzhou, Jiangsu (CN)

(72) Inventors: Zhiqi Wang, Suzhou, Jiangsu Province (CN); Zhijie Shen, Jiangsu (CN); Jiawei Chen, Jiangsu (CN)

(73) Assignee: China Wafer Level CSP Co., Ltd., Suzhou, Jiangsu (CN)

(21) Appl. No.: 15/767,630

(22) PCT Filed: Nov. 22, 2016
(86) PCT No.: PCT/CN2016/106768

§ 371 Date: Apr. 11, 2018

(30) Foreign Application Priority Data
Nov. 27, 2015 (CN) 201510845832.8
Nov. 27, 2015 (CN) 201520964409.5

(51) Int. Cl. H01L 27/146

(52) U.S. Cl. CPC H01L 27/14634; H01L 27/14636

(57) ABSTRACT

An image sensor chip package and an image sensor chip packaging method are provided. The image sensor chip package includes: an image sensor chip; a control chip configured to control the image sensor chip; a first substrate electrically connected to the image sensor chip; and a second substrate electrically connected to the control chip. The first substrate is stacked above the second substrate and is electrically connected to the second substrate.

The present application claims priority to Chinese Patent Application No. 201510845832.8, titled “IMAGE SENSING CHIP PACKAGING STRUCTURE AND METHOD” filed on Nov. 27, 2015 with the State Intellectual Property Office of People's Republic of China and Chinese Patent Application No. 201520964409.5, titled “IMAGE SENSING CHIP PACKAGING STRUCTURE” filed on Nov. 27, 2015 with the State Intellectual Property Office of People's Republic of China, both of which are incorporated herein by reference in their entireties.

### FIELD

The present disclosure relates to a packaging technology for a semiconductor chip, and in particular to a packaging technology for an image sensor chip.

### BACKGROUND

Image sensor chip serving as a functional chip for image acquisition is usually used in a camera of an electronic product. Benefiting from the continuous and vigorous development of camera phones, the market demands on image sensor chip keeps growing in the future. In addition, a considerable application scale of image sensor chips is also brought by prevalent network real-time communication services such as Skype, rise of security monitoring market and rapid development of global automotive electronics. Meanwhile, the packaging technology for the image sensor chip is also developed rapidly.

Package-on-package (POP) technology is one of popular three-dimensional stacking technologies which are developed for IC package of a mobile device such as a smart phone and a tablet computer and which can be applied to system integration. When iPhone is exhibited by Apple in 2007, iPhone is unpacked and presented to people, and the POP technology is then presented to people. The ultra thin package in the POP technology becomes a hot spot of the current packaging technologies, and meets a high integration requirement of the market.

How to apply the package-on-package technology to the field of image sensor chip packaging to meet the market requirement becomes the technical problem desired to be solved by those skilled in the art.

### SUMMARY

A new image sensor chip package and a new image sensor chip packaging method are provided according to the present disclosure, in which the package-on-package technology is applied to the image sensor chip packaging. In this way, a size of the image sensor chip package is reduced and an integration degree of an image sensor chip is improved.

An image sensor chip package is provided according to the present disclosure. The image sensor chip package includes an image sensor chip, a control chip configured to control the image sensor chip, a first substrate and a second substrate. The first substrate is electrically connected to the image sensor chip, the second substrate is electrically connected to the control chip, and the first substrate is stacked above the second substrate and is electrically connected to the second substrate.

Optionally, both the image sensor chip and the control chip are arranged between the first substrate and the second substrate.

Optionally, one surface of the image sensor chip is arranged with a photosensitive region and a contact pad on a region other than the photosensitive region, the contact pad is electrically connected to the first substrate, the first substrate includes an opening penetrating the first substrate, and the photosensitive region is exposed from the opening.

Optionally, the other surface of the image sensor chip is arranged with a black glue layer.

Optionally, the image sensor chip package further includes a protective cover plate. The protective cover plate covers the opening and the opening is arranged between the protective cover plate and the image sensor chip.

Optionally, the control chip is electrically connected to the second substrate via a solder wire.

Optionally, the first substrate is electrically connected to the second substrate via a first solder bump block.

Optionally, a surface of the second substrate not electrically connected to the first substrate is arranged with a second solder bump block.

An image sensor chip packaging method is further provided according to the present disclosure. The method includes: providing an image sensor chip and a control chip configured to control the image sensor chip; providing a first substrate, and electrically connecting the image sensor chip to the first substrate; providing a second substrate, and electrically connecting the control chip to the second substrate; and stacking the first substrate above the second substrate, and electrically connecting the first substrate to the second substrate.

Optionally, when the first substrate is stacked above the second substrate, both the image sensor chip and the control chip are arranged between the first substrate and the second substrate.

Optionally, the method further includes: before the image sensor chip is electrically connected to the first substrate, arranging an opening penetrating the first substrate in the first substrate. One surface of the image sensor chip is arranged with a photosensitive region and a contact pad on a region other than the photosensitive region, and the photosensitive region is exposed from the opening when the image sensor chip is electrically connected to the first substrate.

Optionally, the method further includes: covering the opening with a protective cover plate. The opening is arranged between the protective cover plate and the image sensor chip.

Optionally, the method further includes: coating a black glue layer on the other surface of the image sensor chip with a coating process.

Optionally, the image sensor chip is electrically connected to the first substrate with a flip-chip process.

Optionally, the control chip is electrically connected to the second substrate with a wire bonding process.

Optionally, the first substrate or the second substrate is arranged with a first solder bump block, and the first substrate is electrically connected to the second substrate via the first solder bump block with a reflow soldering process.

Optionally, the method further includes: before the control chip is electrically connected to the second substrate, arranging a second solder bump block on a surface of the second substrate not electrically connected to the first substrate.

The new image sensor chip package and the new image sensor chip packaging method are provided according to the solutions of the present disclosure, in which the package-on-package technology is applied to the image sensor chip packaging. In this way, the size of the image sensor chip package is reduced and the integration degree of the image sending chip is improved.

### BRIEF DESCRIPTION OF THE DRAWINGS

FIG. 1 is a schematic diagram of an image sensor chip package according to an embodiment of the present disclosure; and

FIGS. 2(a) to 2(f) are schematic diagrams showing a process of packaging an image sensor chip according to an embodiment of the present disclosure.

### DETAILED DESCRIPTION OF EMBODIMENTS

Hereinafter, embodiments of the present disclosure are described in detail in conjunction with the drawings. The embodiments are not intended to limit the present disclosure, and transformations made by those skilled in the art in structure, method or function based on these embodiments all fall within the scope of protection of the present disclosure.

It should be noted that, the provided drawings are only for helping to understand the embodiments of the present disclosure, and should not be explained to inappropriately limit the present disclosure. For clarity, the size shown in the drawings is not drawn to scale, and may be zoomed in, zoomed out and changed in other manners. In addition, a three-dimensional size containing length, width and depth should be included in an actual fabrication.

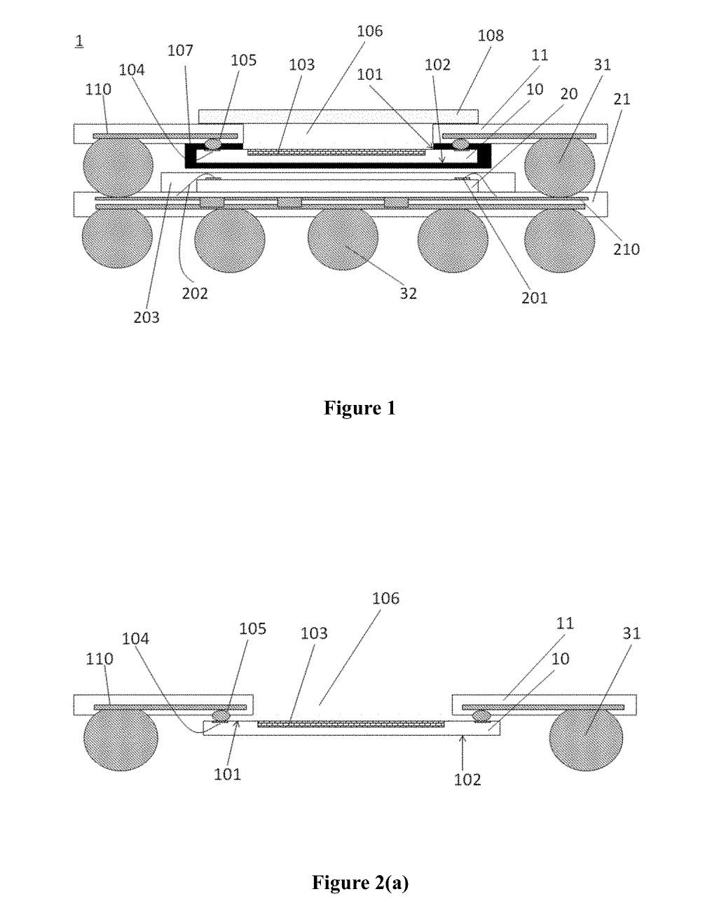

Referring to FIG. 1, FIG. 1 is a schematic diagram of an image sensor chip package according to an embodiment of the present disclosure. An image sensor chip package 1 includes an image sensor chip 10, a control chip 20, a first substrate 11 and a second substrate 21. The image sensor chip 10 is electrically connected to the first substrate 11. The control chip 20 is electrically connected to the second substrate 21. The first substrate 11 is stacked above the second substrate 21 and is electrically connected to the second substrate 21. Therefore, a package-to-package structure of the image sensor chip is formed.

With the package-on-package structure, the image sensor chip has an improved integration degree and a reduced package size.

In an implementation, the image sensor chip 10 is a semiconductor chip having at least an image sensing unit. The image sensing unit may be a CMOS sensor or CCD sensor. The image sensor chip 10 may further include an associative circuit connected to the image sensing unit.

The control chip 20 is configured to control the image sensor chip 10. The function of the control chip 20 is not limited herein, as long as an electric signal is transmitted between the control chip 20 and the image sensor chip 10, that is, the “control” herein can be achieved.

The image sensor chip 10 in the embodiment is a semiconductor chip having a CMOS sensor. The image sensor chip 10 includes a first surface 101 and a second surface 102 opposite to each other. A photosensitive region 103 and a contact pad 104 on a region other than the photosensitive region 103 are arranged on the first surface 101. The contact pad 104 is electrically connected to the photosensitive region 103 (not shown in FIG. 1).

The image sensor chip 10 is electrically connected to the first substrate 11. The first substrate 11 includes a first solder joint, and a solder bump spot 105 is formed on the contact pad 104 or the first solder joint. The solder bump spot 105 may be made of gold, tin-lead or other lead-free metal material. The contact pad 104 is electrically connected to the first solder joint via the solder bump spot 105 with a flip-flop process, to electrically connect the image sensor chip 10 to the first substrate 11.

In order to further reduce the thickness of the image sensor chip package and improve the integration degree, both the image sensor chip 10 and the control chip 20 are arranged between the first substrate 11 and the second substrate 21 in the embodiment.

In the embodiment, both the photosensitive region 103 and the contact pad 104 of the image sensor chip 10 are arranged on the first surface 101 of the image sensor chip 10, and the image sensor chip 10 is electrically connected to the first substrate 11 with the flip-flop process. An opening 106 is arranged in the first substrate 11 to make the photosensitive region 103 be sensitive to external light rays. The opening 106 penetrates the first substrate 11 and the photosensitive region 103 is exposed from the opening 106.

In order to eliminate interference from light rays, a black glue layer 107 is arranged at least on the second surface 102 of the image sensor chip 10. Referring to FIG. 1, the second surface 102 and side surfaces of the image sensor chip 10 are clad by the black glue layer 107.

The opening 106 is covered by a protective cover plate 108 and the opening 106 is arranged between the protective cover plate 108 and the image sensor chip 10. In this way, the image sensor chip 10 is protected and the photosensitive region 103 is prevented from being contaminated by dusts and the like.

The opening 106 is covered by the protective cover plate 108 with sealant. The second surface 102 and the side surfaces of the image sensor chip 10 are hermetically clad by the black glue layer 107. In this way, a sealed cavity is surrounded by the protective cover plate 108, the opening 106 and the image sensor 10, for preventing the photosensitive region 103 from being contaminated by dusts and the like.

In the embodiment, the protective cover plate 108 is made of optical glass, which has a good light transmission, thereby facilitating projection of light ray to the photosensitive region 103. It is readily conceived by those skilled in the art that, an optical film may be arranged on a surface of the protective cover plate to further improve the optical performance of the protective cover plate 108. For example, an anti-reflective film is arranged on the surface of the protective cover plate 108.

The control chip 20 is electrically connected to the second substrate 21. In an implementation, the control chip 20 is fixed on the second substrate 21 with adhesive. The control chip 20 includes a connection end 201, and the second substrate 21 includes a first connection pad. The connection end 201 is electrically connected to the first connection pad via a solder wire 202 with a wire bonding process, to electrically connect the control chip 20 to the second substrate 21. The solder wire 201 may be made of metal material including copper, tungsten, aluminum, gold, silver and the like.

A package 203 is formed by packaging the protection chip 20 and the solder wire 202, to protect the control chip 20 and the solder wire 202.

The first substrate 11 is stacked above the second substrate 21 and electrically connected to the second substrate 21. In an implementation, the first substrate 11 has a first metal wire layer 110, a first solder joint electrically connected to the first metal wire layer 110 and a second solder joint electrically connected to the first metal wire layer 110. The first solder joint and the second solder joint may be exposed portions of the first metal wire layer 110 on the first substrate 11. The second substrate 21 includes a second metal wire layer 210, a first connection pad electrically connected to the second metal wire layer 210 and a second connection pad electrically connected to the second metal wire layer 210. The first connection pad and the second connection pad may be exposed portions of the second metal wire layer 210 on the second substrate 21. The second solder joint or the second connection pad is arranged with a first solder bump block 31. The second solder joint is electrically connected to the second connection pad via the first solder bump block 31, to electrically connect the first substrate 11 with the second substrate 21.

In the embodiment, both the image sensor chip 10 and the control chip 20 are arranged between the first substrate 11 and the second substrate 21 to further reduce the size of the image sensor chip package. In order to avoid a case that the image sensor chip 10 contacts the control chip 20 or the package 203 of the control chip 20, the size of the first solder bump block 31 is optimized such that the first solder bump block 31 supports and space the first substrate 11 and the second substrate 21. In this way, a space is formed between the image sensor chip 10 and the control chip 20 or the package 203 of the control chip 20. In the embodiment, the thickness of the image sensor chip 10 is about 150 microns, the thickness of the solder bump spot 105 is about 20 microns, the thickness of the package 203 of the control chip 20 is about 250 microns and the thickness of the first solder bump block 31 is about 500 microns.

Of course, the control chip 20 may be arranged on a surface of the second substrate 21 not electrically connected to the first substrate 11, that is, the control chip 20 is not arranged between the first substrate 11 and the second substrate 21.

In order to achieve an electrical connection between the image sensor chip package and other external circuits, in the embodiment, a second solder bump block 32 is arranged on the surface of the second substrate 21 not electrically connected to the first substrate 11, the second solder bump block 32 is electrically connected to the second metal wire layer 210, and the second substrate 21 is electrically connected to the external circuit via the second solder bump block 32.

In an implementation, the size of the second solder bump block 32 is set to be same as the size of the first solder bump block 31, to reducing the effect of thermal stress.

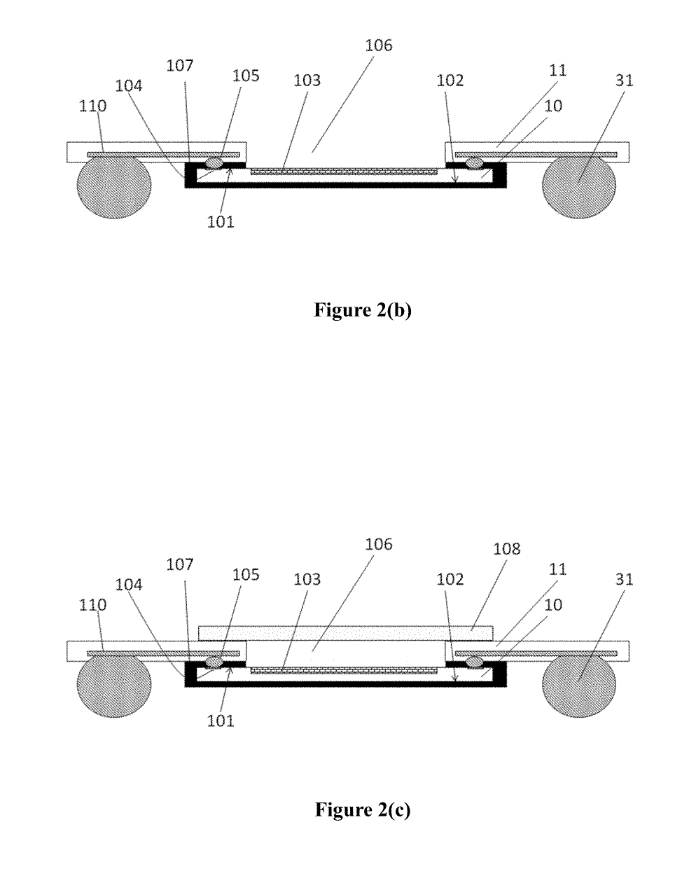

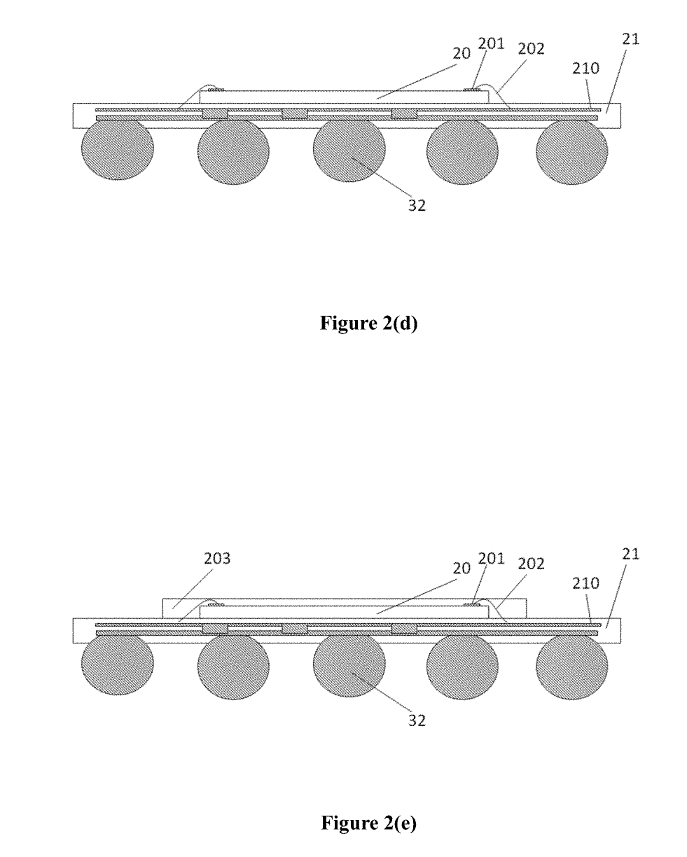

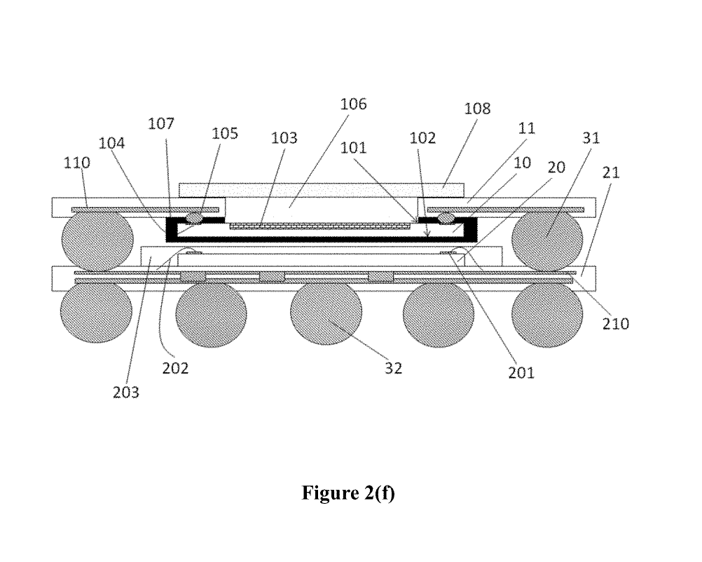

Referring to FIGS. 2(a) to 2(f), FIGS. 2(a) to 2(f) are schematic diagrams showing a process of packaging an image sensor chip according to an embodiment of the present disclosure.

Referring to FIG. 2(a), an image sensor chip 10 and a first substrate 11 are provided, and the image sensor chip 10 is electrically connected to the first substrate 11. The image sensor chip 10 includes a first surface 101 and a second surface 102 opposite to each other. The first surface 101 is arranged with a photosensitive region 103 and a contact pad 104 on a region other than the photosensitive region 103. The contact pad 104 is electrically connected to the photosensitive region 103. The first substrate 11 includes a first metal wire layer 110, a first solder joint electrically connected to the first metal wire layer 110 and a second solder joint electrically connected to the first metal wire layer 110. A solder bump spot 105 is formed on the contact pad 104 or the first solder joint. The contact pad 104 is electrically connected to the first solder joint via the solder bump spot 105 with a flip-flop process, to electrically connect the image sensor chip 10 with the first substrate 11. The first substrate 11 is arranged with an opening 106 which penetrates the first substrate 11, and the photosensitive region 103 is exposed from the opening 106.

Referring to FIG. 2(b), in order to eliminate interference from light rays, a black glue layer 107 is arranged at least on the second surface 102 of the image sensor chip 10. In the embodiment, the second surface 102 and side surfaces of the image sensor chip 10 are clad with the black glue layer 107 with a dispensing process.

Referring to FIG. 2(c), the opening 106 is covered by a protective cover plate 108 and the opening 106 is arranged between the protective cover plate 108 and the image sensor chip 10. In this case, the image sensor chip 10 is protected and the photosensitive region 103 is prevented from being contaminated by dusts and the like. In the embodiment, the protective cover plate 108 is fixed on the first substrate 11 with adhesive.

Referring to FIG. 2(d), a control chip 20 and a second substrate 21 are provided, and the control chip 20 is electrically connected to the second substrate 21. The control chip 20 is fixed on the second substrate 21 with adhesive. The control chip 20 includes a connection end 201. The second substrate 21 includes a second metal wire layer 210, a first connection pad electrically connected to the second metal wire layer 210 and a second connection pad electrically connected to the second metal wire layer 210. The connection end 201 is electrically connected to the first connection pad via a solder wire 202 with a wire bonding process, to electrically connect the control chip 20 with the second substrate 21.

Referring to FIG. 2(e), a package 203 is formed by packaging the protection chip 20 and the solder wire 202, to protect the control chip 20 and the solder wire 202.

Referring to FIG. 2(f), the first substrate 11 is stacked above the second substrate 21 and electrically connected to the second substrate 21. Both the image sensor chip 10 and the control chip 20 are arranged between the first substrate 11 and the second substrate 21. The second solder joint or the second connection pad is arranged with a first solder bump block 31. The second solder joint is electrically connected to the second connection pad via the first solder bump block 31 with a reflow soldering process, to electrically connect the first substrate 11 with the second substrate 21.

In the embodiment, the new image sensor chip package and the new image sensor chip packaging method are provided according to the present disclosure, in which the package-on-package technology is applied to the image sensor chip packaging. In this way, the size of the image sensor chip package is reduced and the integration degree of the image sending chip is improved.

It should be understood that, although the present disclosure is described with embodiments, it is not indicated that each embodiment only includes one independent technical solution. The specification is described in the above way, only for clarity. Those skilled in the art should take the specification as an whole, and other embodiments understandable to those skilled in the art may be formed by appropriately combine the technical solutions of these embodiments.

The above series of detailed descriptions are only descriptions of practicable embodiments of the present disclosure, and are not intended to limit the scope of protection of the present disclosure. Any equivalent embodiment or changes made without departing from the spirit of the present disclosure shall fall within the scope of protection of the present disclosure.

1. An image sensor chip package, comprising:
an image sensor chip;
a control chip configured to control the image sensor chip;
a first substrate electrically connected to the image sensor chip; and
a second substrate electrically connected to the control chip; wherein
the first substrate is stacked above the second substrate and is electrically connected to the second substrate.

2. The image sensor chip package according to claim 1, wherein both the image sensor chip and the control chip are arranged between the first substrate and the second substrate.

3. The image sensor chip package according to claim 1, wherein one surface of the image sensor chip is arranged with a photosensitive region and a contact pad on a region other than the photosensitive region, the contact pad is electrically connected to the first substrate, the first substrate comprises an opening penetrating the first substrate, and the photosensitive region is exposed from the opening.

4. The image sensor chip package according to claim 3, wherein the other surface of the image sensor chip is arranged with a black glue layer.

5. The image sensor chip package according to claim 3, further comprising a protective cover plate, wherein the protective cover plate covers the opening and the opening is arranged between the protective cover plate and the image sensor chip.

6. The image sensor chip package according to claim 1, wherein the control chip is electrically connected to the second substrate via a solder wire.

7. The image sensor chip package according to claim 1, wherein the first substrate is electrically connected to the second substrate via a first solder bump block.

8. The image sensor chip package according to claim 1, wherein a surface of the second substrate not electrically connected to the first substrate is arranged with a second solder bump block.

9. An image sensor chip packaging method, comprising:
providing an image sensor chip and a control chip configured to control the image sensor chip;
providing a first substrate, and electrically connecting the image sensor chip to the first substrate;
providing a second substrate, and electrically connecting the control chip to the second substrate; and
stacking the first substrate above the second substrate, and electrically connecting the first substrate to the second substrate.

10. The image sensor chip packaging method according to claim 9, wherein, when the first substrate is stacked above the second substrate, both the image sensor chip and the control chip are arranged between the first substrate and the second substrate.

11. The image sensor chip packaging method according to claim 9, further comprising: before the image sensor chip is electrically connected to the first substrate, arranging an opening penetrating the first substrate in the first substrate, wherein one surface of the image sensor chip is arranged with a photosensitive region and a contact pad on a region other than the photosensitive region, and the photosensitive region is exposed from the opening when the image sensor chip is electrically connected to the first substrate.

12. The image sensor chip packaging method according to claim 11, further comprising: covering the opening with a protective cover plate, wherein the opening is arranged between the protective cover plate and the image sensor chip.

13. The image sensor chip packaging method according to claim 11, further comprising: coating a black glue layer on the other surface of the image sensor chip with a coating process.

14. The image sensor chip packaging method according to claim 9, wherein the image sensor chip is electrically connected to the first substrate with a flip-chip process.

15. The image sensor chip packaging method according to claim 9, wherein the control chip is electrically connected to the second substrate with a wire bonding process.

16. The image sensor chip packaging method according to claim 9, wherein the first substrate or the second substrate is arranged with a first solder bump block, and the first substrate is electrically connected to the second substrate via the first solder bump block with a reflow soldering process.

17. The image sensor chip packaging method according to claim 9, further comprising: before the control chip is electrically connected to the second substrate, arranging a second solder bump block on a surface of the second substrate not electrically connected to the first substrate.
